(19) United States
(12) Patent Application Publication
(10) Pub. No.: US 2026/0056253 A1
(43) Pub. Date: Feb. 26, 2026

(54) DATA-BASED CONDITION MONITORING METHOD FOR MONITORING GRID-SIDE COMPONENTS

(71) Applicant: Siemens Aktiengesellschaft, München (DE)

(72) Inventors: Marc Hiller, Bretten (DE); Peter Köllensperger, Heroldsberg (DE); Andreas Liske, Pfinztal (DE); Savvas Tsotoulidis, Lamia (GR)

(73) Assignee: Siemens Aktiengesellschaft, München (DE)

(21) Appl. No.: 19/305,431

(22) Filed: Aug. 20, 2025

(30) Foreign Application Priority Data
Aug. 21, 2024 (EP) 24195582.2

(51) Int. Cl. G01R 31/30

(52) U.S. Cl. CPC G01R 31/3004

(57) ABSTRACT

A computer-implemented method for determining a degradation progression of a load connected downstream of a power converter or of an intermediate circuit includes measuring a time profile of a control variable controlling an output voltage or an output current of the power converter or of the intermediate circuit supplied to the load, determining an amplitude of at least one higher harmonic of a fundamental oscillation of the captured time profile, comparing the amplitude with a reference amplitude associated with a known degradation progression of the load; and determining the degradation progression of the load based on the comparison. A computer-implemented apparatus, a computer program product and a system for determining a degradation progression of a load connected downstream of the power converter and/or the intermediate circuit are also disclosed.

### CROSS-REFERENCES TO RELATED APPLICATIONS

This application claims the priority of European Patent Application, Serial No. EP 24195582, filed Aug. 21, 2024, pursuant to 35 U.S.C. 119(a)-(d), the disclosure of which is incorporated herein by reference in its entirety as if fully set forth herein.

### BACKGROUND OF THE INVENTION

The invention relates to a computer-implemented method, a computer-implemented apparatus, a system and a computer program product for determining a degradation progression of a load connected downstream of a power converter and/or of an intermediate circuit.

The following discussion of related art is provided to assist the reader in understanding the advantages of the invention, and is not to be construed as an admission that this related art is prior art to this invention.

Electrical components are generally subject to an ageing process. This can, for example, be caused by repeated heating and cooling of the components concerned during normal operation, by material defects present in the material of the electric components, etc. This ageing process generally leads to a limited service life for the components concerned, which consequently have to be replaced after a certain period of use.

In some cases, ageing can also occur in electric drive systems as a result of their use. This ageing can, for example, occur due to reduced rotor flux as a result of the degradation of magnets in an electric drive system and/or increased resistance of a rotor winding. In some cases, contact resistance at a rotor contact point (for example an electrically conductive transition from the stator to the rotor) can also increase. These ageing effects can have an impact on the behavior of the electric drive unit and thus also on the properties of the control used, in order, for example, to ensure that a desired supply voltage or a desired supply current is always made available to an electric drive.

The remaining service life of components in a system as mentioned above (for example in a power converter and/or an electric drive unit) can often be difficult for a plant operator to ascertain. Determining the remaining service life can often be a challenge both for the manufacturer of the respective electric component and for the system administrator responsible for implementing the respective electric component. In this regard, manufacturers often perform offline calculations to determine the expected service life of a component (for example a power transformer) and then list this in their documentation. These calculations are generally based on load profiles and product usage such as may occur over an ideal product cycle, while taking into account typical constraints, such as, for example, temperature, humidity, altitude, etc.

The remaining service life can, for example, be ascertained by regular maintenance of the components concerned. In one such case, for example, two maintenance strategies can be considered. It may be possible to define maintenance intervals at which the components to be serviced are most likely to be still functional based on the known load profiles and specified ambient conditions. However, the choice of these maintenance intervals can often result in components that possibly have still have a considerable remaining service life being replaced and this can result in (unnecessarily) high costs and material usage.

If downtimes of the electric system can be accepted, a further maintenance strategy can also entail replacing the component concerned when it has actually failed. Although this can reduce the (unnecessary) costs associated with premature replacement, it can lead to an unexpected shutdown of the electric system and thus, for example, to a production line being shut down. Depending upon the resulting defect, this can lead to unexpectedly high costs. Selecting maintenance intervals optimized for the plant and application concerned can lead to a global cost reduction and minimize the downtime of the electric system.

The use of so-called condition monitoring methods enables the time when maintenance of the electric system should be performed to be optimized by ascertaining the remaining service life of electric components or the progression of a current degradation process.

In general, condition monitoring can be divided into three different classes of approaches:

In the context of sensor-based condition monitoring systems, additional/dedicated sensor systems and/or complex measuring circuits can be used to directly measure variables of an electric system, allowing conclusions to be drawn about a current degradation progression of electric components. Herein, the complexity and the implementation costs of such a system can increase significantly. Furthermore, a distinction can be made between measurement systems that are used online during operation of a power-converter system and external test equipment that is only used for measurement at defined (predetermined) intervals.

In the context of model-based condition monitoring systems, it is attempted to overcome some of the aforementioned problems at least partially by modeling. In these models, the ageing process is implemented physically or stochastically. The model is then run online during operation with load profiles and ambient conditions as input variables. The result can be a stochastic evaluation of the remaining service life or the current severity of the damage. Despite the elimination of additional measuring circuits, the challenge is still to construct a model of sufficient quality.

Data-based condition monitoring systems can be configured such that existing measurement and state variables can be used to create patterns that allow conclusions to be drawn about the change in a degradation indicator and about the occurrence of ageing. Herein, the information content of various possible measurement signals and state variables can be analyzed and signal processing options can be utilized. This can be based on statistical methods or artificial intelligence methods.

However, known condition monitoring methods do not yet allow a satisfactory determination of degradation progression under all circumstances, since these require overly complex hardware, overly complex modeling or time-consuming data analysis. In some cases, currently used condition monitoring methods are simply too inaccurate for field use.

It is possible, for example in the presence of an (electric) drive, to base condition monitoring of a power converter on capturing mechanical vibrations and/or electric signals associated with the operation of the drive. One possibility in this context can be the use of motor current signature analysis (MCSA), which is, for example, used to identify mechanical faults in a drive, such as, for example, misalignment, imbalance, loose motor feet, cavitation effects (for example in pumps) etc. However, this is substantially based on the evaluation of mechanical parameters and therefore cannot ensure the required prediction accuracy in all cases.

Since, in some cases, power converters can be difficult to access (for example in the case of offshore wind farms), condition monitoring is particularly important. In some cases, a power converter can also be used to feed electric power into a power grid. Herein, degradation or other undesirable behavior of a power grid is generally not taken into account or characterized. To characterize a power grid, limit values of the power grid such as, for example, grid voltage and/or a frequency of the power grid in the tolerance range (for example approximately 48-52 Hz) are generally monitored. Herein, stabilization of a grid-side current control (of the power grid, for example) is generally achieved by a robust phase-locked loop (PLL), which remains stable for both strong and weak grids. On the other hand, the dynamics of the control are reduced so that stable operation is achieved over the entire operating range.

With current condition monitoring methods, it is in particular generally not possible to characterize a load that, for example, follows a power converter, or at least not possible to a satisfactory extent.

It would therefore be desirable and advantageous to provide an improved condition monitoring method to obviate prior art shortcomings and to enable a degradation progression of a load connected downstream of a power converter and/or of an intermediate circuit to be determined.

### SUMMARY OF THE INVENTION

According to a first aspect of the invention, a computer-implemented method for determining a degradation progression of a load connected downstream of a power converter and/or of an intermediate circuit includes capturing a time profile of a control variable intended to control an output voltage and/or an output current of the power converter and/or the intermediate circuit, wherein the output voltage and/or the output current is intended to be supplied to the load, and determining an amplitude of at least one higher harmonic of a fundamental oscillation of the captured time profile. Furthermore, the computer-implemented method may include comparing the amplitude with a reference amplitude that is associated with a known degradation progression of the load, and determining the degradation progression of the load based on the comparison.

In the present case, a degradation progression can be understood as the progression of an ageing process of the power converter (also referred to herein as an inverter) and/or the electric drive unit. Progression of the degradation can be associated with an increasing probability of failure of the power converter and/or the electric drive unit (for example due to a defect). The time profile may be captured at predetermined (discrete) points in time and/or may be captured continuously during operation of the power converter and/or the electric drive unit.

The captured time profile can extend over a duration of less than one second. In some cases, the captured time profile can extend over one second to ten seconds, in some cases over a duration of eleven seconds to 30 seconds, in other cases over a duration of 31 seconds to 60 seconds. In other cases, the duration can also extend over several minutes (for example two, three, four, five, ten, 15, 20, 25, 30, 35, 40, 45, 50, 55 minutes). However, the time profile may also extend over a duration of more than one hour or over several days.

In some cases, the determination of a degradation progression can take place not only as an absolute establishment (namely that degradation has occurred) but in particular also, for example, as a step-by-step establishment of how far the degradation has already progressed. In this way, a statement can be made, for example, to the effect that the power converter has already reached, for example, 10%, 20%, 30%, 40%, 50%, 60%, 70%, 80%, 90%, 99% of its expected service life, which can be used as a starting point for deciding whether the power converter should be replaced.

The reference amplitude can be derived, at least in part, from amplitudes determined in the past for analogously captured time profiles of the control variable and their (systematic) assignment to a degradation progression of the load to be characterized. This can enable a direct assignment of a degradation progression to an amplitude present with this degradation progress.

In some cases, degradation of the load may result in a parameter associated with the operation of the load such as, for example, an input current or an input voltage, which is provided by the power converter and/or the intermediate circuit of the load. This may be reflected in an increase or decrease in the output current and/or the output voltage of the power converter. This change in the output current and/or the output voltage may affect an effort of the controller, which may be configured to maintain the output current and/or the output voltage at a constant value. This can, for example, be reflected in a change in the control variable if it is used to stabilize the output current and/or the output voltage.

The degradation progression determined can, for example, be provided to a user in text form and/or graphically and/or as spoken content via a user interface (for example a display, tablet, etc.).

In this way, the functional spectrum of the condition monitoring can be efficiently extended from the sole characterization of a power converter to the characterization of a load connected to the power converter and hence conclusions can be drawn from the monitoring of a parameter associated with a power converter about loads connected to the power converter and thus ultimately the degradation progression of this load can be determined. Furthermore, the computer-implemented method can be inexpensive to implement, since it can be preferably provided on a software basis and, for example, power converters that have already been delivered can be retrofitted accordingly.

According to another advantageous feature of the invention, the load may be an electric drive unit, a combination of a resistor and an inductor, a cable, a filter and/or a power grid.

The combination of the resistor and the inductor may result in an RL load.

If the load is provided as a cable, the determined degradation of the cable may be, for example, a cable break (for example, a complete break of the cable or of individual wires of the cable).

The power grid may be a power grid with a frequency of 50 Hz and a grid voltage of 230 V. Alternatively, the power grid may also be a power grid with a frequency of 60 Hz and a voltage of 110 V.

In this way, efficient condition monitoring can be provided for a plurality of loads connected downstream of a power converter and/or of an intermediate circuit.

According to another advantageous feature of the invention, the control variable may be a proportional, P, and/or an integral, I, component of a PI controller and/or a value provided by a fault memory.

The I component and/or the P component of the PI controller may be obtained by multiplying a fault signal (i.e. a difference between a setpoint variable and an actual variable of the output voltage and/or the output current) with a predetermined P or I value. The P or I value is preferably a scalar. In some cases, the at least one state variable associated with the control may also be derived from a sum of the I component and the P component.

The output value of the fault memory may be associated with a repetitive-control controller. The concept of a repetitive-control controller may be based on the fact that for a certain difference between the setpoint value and the actual value (and/or for a specific gradient of the signal to be controlled) it is already known which control variable (for example which actuating voltage) can be used to minimize or zero the specific difference. In this way, sufficient control may also be achieved for higher-frequency signal components that cannot, for example, be adequately compensated by the I component of a PI controller (for example due to its integrating behavior).

The comparison may be used as the basis not only for determining a degradation progression of the power converter (since, for example, a deviation in the output voltage and/or the output current can be determined in this way), which can be regulated or compensated by a PI controller and/or fault memory-based control up to a certain degradation progress, but additionally or alternatively also for determining a degradation progression of the electric drive unit itself. This can be achieved because when the degradation of the load progresses, its input current or input voltage can change, which may be compensated accordingly by the (upstream) power converter up to a certain degradation progression of the load (for example by adjusting the output current and/or the output voltage of the power converter so that a required respective input voltage or a respective input current can be provided to the load).

In this way, the functional spectrum of the condition monitoring may be extended from possibly determining the degradation progression of a power converter to determining a load connected downstream of the power converter (and/or of an intermediate circuit) by only using parameters that are limited to the power converter (and/or the intermediate circuit). Hence, this eliminates the need to implement further dedicated hardware (since the only variables used are those that are already present during the operation of the power converter and/or the intermediate circuit) and efficient condition monitoring is provided. Hence, overall, this enables improved condition monitoring without an increase in the system complexity.

According to another advantageous feature of the invention, determining the amplitude may further include determining an amplitude of a DC component, a 1^{st} harmonic, a 2^{nd} harmonic and/or a 6th harmonic.

A degradation progression may then be determined based on a plurality of indicators derived from the captured time profile. In particular, different causes for a degradation progression may then be determined, since, for example, some causes of degradation are only reflected in some higher harmonics (for example only the 1^{st} harmonic and/or the 2^{nd} harmonic and/or the 6^{th} harmonic), but not in all harmonics.

The determined change in the aforementioned variables (considered individually or in combination) may thus be used, for example, as an indicator for asymmetries in relation to an electric angle of a three-phase or alternating current system.

The determination of the higher harmonics may provide information about the degradation state of the power converter (and/or a semiconductor module thereof), the sensor systems used (for example temperature sensors, vibration sensors, etc.) and the degradation state of a mains filter.

According to another advantageous feature of the invention, the computer-implemented method may further include capturing a parameter associated with the load, wherein the parameter is a temperature of the load, a speed of an electric drive unit, a rotor position angle of an electric drive unit and/or an ambient temperature of the load, and determining the degradation progression of the load based on the comparison and the captured parameter.

A parameter associated with the load can be understood as a parameter that is not directly associated with the control of an output voltage and/or an output current of the power converter and/or the intermediate circuit.

The temperature of the load can, for example, be understood as an internal and/or external temperature of an electric drive unit if the load is provided as an electric drive unit. The ambient temperature of the load can be understood as a temperature of the environment in which the load is located.

A rotor position angle can be understood as an angle of a rotor of an electric drive unit relative to a predefined rotor position.

According to another advantageous feature of the invention, the power converter and/or the intermediate circuit may be part of a grid-side power-converter system.

In some cases, the power converter or the intermediate circuit may be constructed to feed a generated electric power into the power grid (for example by adjusting the generated power so as to meet the requirements of the power grid (for example with regard to frequency, voltage, etc.)).

In this way, the degradation progression may be monitored in a power grid.

According to another advantageous feature of the invention, the computer-implemented method may further include capturing a plurality of time profiles and determining a respective amplitude of the at least one harmonic for each of the captured time profiles. The computer-implemented method may further comprise determining a variance of the determined amplitudes and determining progression of the degradation based at least in part on the determined variance.

The variance can thus, for example, be used to derive information about the strength of the grid (i.e. whether it is to be regarded as strong or weak).

A weak grid can, for example, result when the ratio of short-circuit current to grid impedance decreases due to a limited short-circuit current of a power converter.

In some cases, the plurality of captured time profiles can be comprised of profiles captured at equidistant time intervals. The captured time profiles can in each case have the same temporal length. In some cases, at least one of the captured time profiles may have a temporal length that differs from the remaining time profiles.

In this way, it can, for example, be efficiently established whether, for example, a power grid exhibits undesirable flicker behavior (for example if the variance determined exceeds a predetermined threshold value of the variance), such as, for example, can be pronounced in weak grids.

According to another advantageous feature of the invention, the computer-implemented method may further include determining a phase associated with the higher harmonic and comparing the phase with a reference phase. Furthermore, the computer-implemented method may include determining degradation progression of the load based on the comparison of the amplitude and the comparison of the phase.

In some cases, for example for sequentially captured time profiles, a phase position of the captured time profiles relative to one another can be determined.

In this way, determining the degradation progression of a load may be based not only on a comparison of amplitudes, but can also include phase information. This can increase the prediction accuracy of the degradation progression and/or enable the determination of a degradation progression which is based on a cause of degradation that is not, for example, manifested in a corresponding amplitude change, but is, for example, reflected in a phase. Hence, the computer-implemented method for determining a degradation progression of a load can be further improved efficiently and cost-effectively.

According to another advantageous feature of the invention, when the load is a power grid, the control of the power converter may be configured to provide reactive power, compensate asymmetric loads and/or perform frequency stabilization.

In the present case, reactive power is to be understood as energy that can be provided by the controller (for example by energy stored in the controller's inductors) and supplied to the power grid. In some cases, the energy stored in the controller's inductors may have been absorbed by the power grid.

Supplying reactive power can, for example, be advantageous when connecting or disconnecting power grid subscribers. Likewise, supplying reactive power can be advantageous when an energy source is connected to or disconnected from the power grid.

In the present case, frequency stabilization is to be understood as stabilization of the frequency of the current to be fed into the power grid. This can, for example, be advantageous if the load is a power grid and it has been established that the degradation has affected a frequency of the power grid and thus may have led to a deviation of the frequency from 50 Hz (alternatively, 60 Hz). Hence, the controller can at least partially counteract such a deviation.

In this way, the findings from the determination of the degradation progression of the load can also be used to provide improved feed-in of electric energy into a power grid. This can support grid-friendly operation of the power converter.

According to another advantageous feature of the invention, the power converter and/or the intermediate circuit can be part of a photovoltaic system or a wind turbine.

This can enable monitoring of a degradation progression of the feed-in of electric power generated by the photovoltaic system and/or by the wind turbine into a power grid.

This can make it possible to determine a degradation progression of loads (or components thereof) that are, for example, difficult to reach in normal operation (for example if the wind turbine is implemented as an offshore farm).

According to another advantageous feature of the invention, the power converter may be a 3-phase 2-level inverter, wherein the power converter may include at least one semiconductor module, preferably six semiconductor modules, and wherein the at least one semiconductor module may preferably be an insulated gate bipolar transistor, IGBT, or a SiC metal oxide semiconductor field-effect transistor, MOSFET.

In some cases, the power converter may include one semiconductor module, two, three, four, five, six, seven, eight, nine, ten or more semiconductor modules.

It should be noted that the aspects of the invention mentioned herein are not limited to IGBTs or MOSFETs as semiconductor modules, but aspects of the invention can also be applied to other semiconductor modules not explicitly described herein.

In some cases, the power converter can be provided as a three-phase bridge circuit.

This can enable a particularly compact and cost-effective implementation of a power converter

According to a second aspect of the present invention, a computer program product embodied on a non-transitory computer-readable medium and including instructions which, when the program is executed by a computer, cause the computer to execute the method as described herein.

In some cases, the computer program product can, for example, be integrated into drive control software of the electric devices. In some cases, at least computational operations to be performed (for example determining the deviation and/or a cause of degradation and/or a degradation progress) can be performed by an entity separate from the power converter and/or the electric drive unit (for example a server system). In this way, computationally intensive operations can be executed by dedicated hardware.

A computer program product may, for example, be provided or supplied as a storage medium, such as, for example, a memory card, USB stick, CD-ROM, DVD, or also in the form of a file that can be downloaded from a server in a network. This can, for example, take place in a wireless communication network by transferring a corresponding file with the computer program product or the computer program means.

According to a third aspect of the present invention, a computer-implemented apparatus for determining a degradation progression of a load connected downstream of a power converter and/or of an intermediate circuit. includes a capturing unit for capturing a time profile of a control variable which is intended to control an output voltage and/or an output current of the power converter and/or the intermediate circuit, wherein the output voltage and/or the output current is intended to be supplied to the load, and a first determining unit for determining an amplitude of at least one higher harmonic of a fundamental oscillation of the captured time profile. Furthermore, the computer-implemented apparatus may include a comparison unit for comparing the amplitude with a reference amplitude, wherein the reference amplitude is associated with a known degradation progression of the load, and a second determining unit for determining the degradation progression of the load based on the comparison.

The respective unit, for example each of the capturing unit, the determining units, the comparison unit may be implemented in hardware and/or software. In a hardware implementation, the respective unit may be embodied as an apparatus or as part of an apparatus, for example as a computer or microprocessor or as a control computer of a vehicle. In a software implementation, the respective unit may be embodied as a computer program product, as a function, as a routine, as part of a program code or as an executable object.

According to another advantageous feature of the invention, the computer-implemented apparatus may further include an execution unit for executing the computer program product as described herein and/or a further execution unit for executing the method as likewise described herein.

The execution unit may, for example, be provided as a computer, processor, field programmable gate array (FPGA) or a combination thereof.

According to a fourth aspect of the present invention, a system for determining a degradation progression of a load connected downstream of a power converter and/or of an intermediate circuit includes the computer program product as described herein. Furthermore, the system may include a computer-implemented apparatus as described herein.

The computer program product may be included in the computer-implemented apparatus. In alternative examples, the computer program may also be included in a unit provided remotely from the computer-implemented apparatus. In the latter exemplary case, the computer-implemented apparatus may access the computer program product via a network (for example a local network or the Internet) or a USB connection.

It should be noted that the determination of a degradation progression described herein is not restricted only to a load connected downstream of the power converter or of an intermediate circuit, but can also be used in an analogous manner to determine a degradation progression of the power converter and/or the intermediate circuit itself.

The embodiments and features described for the proposed apparatus apply accordingly to the proposed method.

Furthermore, possible implementations of the invention also include combinations of features or embodiments described above or below with respect to the exemplary embodiments not explicitly mentioned. Herein, the person skilled in the art will also add individual aspects as improvements or additions to the respective basic form of the invention.

Further advantageous embodiments and aspects of the invention are the subject matter of the dependent claims and the exemplary embodiments of the invention described below. The invention will also be described in more detail below with reference to the accompanying figures.

In particular, it should be noted that the above-described method or the above-described apparatus, the above-described computer program product and the system are not limited to power converters and/or electric drive units, but can also be used in other industrial contexts.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIGS. 1A-1C show a cross-section through an IGBT (FIG. 1A) and possible causes of degradation of a power converter (FIGS. 1B and 1C);

FIG. 2 shows an exemplary system showing the interaction of a power converter in a possible context according to the invention;

FIG. 3 shows an exemplary equivalent circuit diagram of a three-phase bridge circuit;

FIG. 4 shows an exemplary αß diagram;

FIG. 5 shows an exemplary system flow diagram;

FIG. 6 shows an exemplary system flow diagram;

FIG. 7 shows exemplary event clouds for determining a degradation state of a load connected downstream of a power converter (and/or of an intermediate circuit);

FIG. 8 shows exemplary diagrams for determining a degradation state of a load connected downstream of a power converter (and/or of an intermediate circuit);

FIG. 9 shows a flowchart of an exemplary computer-implemented method;

FIG. 10 shows an exemplary computer-implemented apparatus; and

FIG. 11 shows an exemplary system.

### DETAILED DESCRIPTION OF PREFERRED EMBODIMENTS

Throughout all the figures, same or corresponding elements may generally be indicated by same reference numerals. These depicted embodiments are to be understood as illustrative of the invention and not as limiting in any way. It should also be understood that the figures are not necessarily to scale and that the embodiments may be illustrated by graphic symbols, phantom lines, diagrammatic representations and fragmentary views. In certain instances, details which are not necessary for an understanding of the present invention or which render other details difficult to perceive may have been omitted.

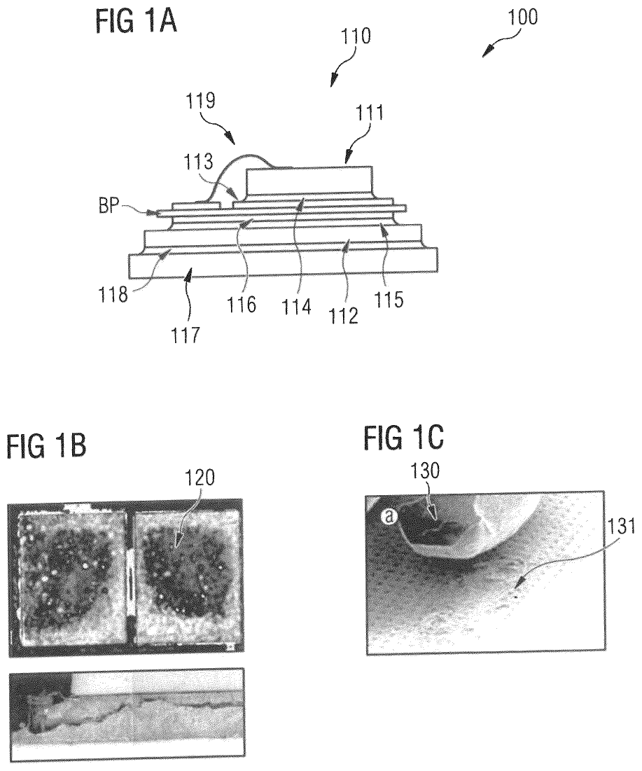

Turning now to the drawing, and in particular to FIG. 1A, there is shown an exemplary cross-section through an IGBT 110, that may, for example, be contained in a power converter or transformer.

In the present case, a power converter can be understood as an apparatus which, for example, converts alternating current into direct current (rectifiers) or an apparatus which converts a direct current into an alternating current (inverters). Furthermore, a power converter may also be understood as an inverter operating, for example, as a frequency inverter and constructed, for example, to change an alternating current frequency.

The IGBT consists of a chip 111 arranged on a base plate 112. A first copper layer 113 can be arranged between the chip 111 and the base plate 112 in order to enable optimum heat conduction between the chip 111 and the base plate 112.

The chip 111 can be attached to the copper layer 113 by a first solder layer 114. Furthermore, the base plate 112 can be connected to the first copper layer 113 via a second solder layer 115 and a second copper layer 116.

The base plate 112 can be arranged above a cooling plate 117. A heat conductive paste layer 118 can be provided between the base plate 112 and the cooling plate 117.

Furthermore, an upper side of the chip 111 can be connected to a power supply (not shown in FIG. 1A) via a bonding wire 119.

FIG. 1B further shows a possible degradation of a power converter, which can, for example, be caused by degradation of a solder joint 120. Such defects in solder joints can, for example, be caused by (thermal) cracks in the solder and/or by a detachment of the solder joint (for example also by a detachment of a bonding wire from the upper side of the chip 112 or a power supply). Degradation of a solder joint can lead to poorer electric contacting and thus to poorer transmission of electric energy for operating an IGBT 110, for example. This can further lead to an increase in thermal resistance and thus to a change in the forward voltage of the IGBT, which can lead to undesired heating of the IGBT and thus can further advance degradation of the IGBT 110.

FIG. 1C shows a further possible degradation of the power converter, which can, for example, be caused by a detachment of the bonding wire 130 from a power supply 131. In such a case, for example, a contact surface between the bonding wire 130 and the power supply 131 can be reduced by the detachment of the bonding wire 130. This can be understood to increase the resistance of the conductive connection between, for example, an IGBT and an underlying power supply. This increased resistance must, for example, be compensated by output current regulation of the IGBT 110. This can ultimately contribute to heating of the IGBT 110 and thus further advance its degradation.

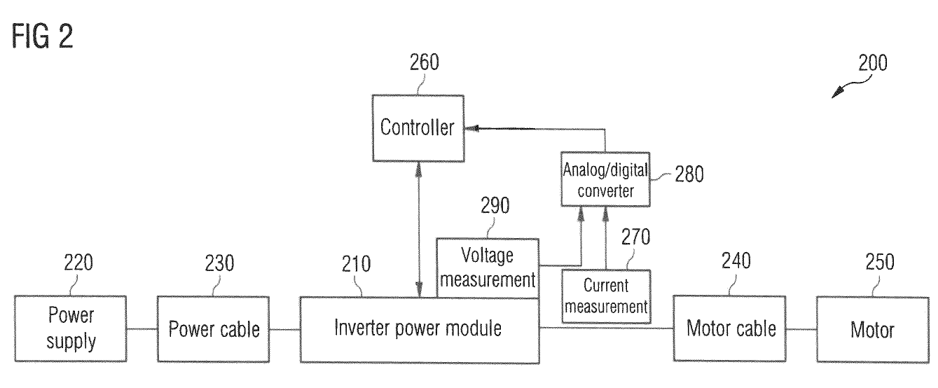

FIG. 2 shows an exemplary system 200 showing the interaction of a power converter (also inverter) in a possible context according to the invention.

In the present case, a power converter is to be understood as an apparatus which, for example, converts alternating current into direct current (rectifiers) or an apparatus which converts a direct current into an alternating current (inverters). Furthermore, a power converter can also be understood as an inverter operating, for example, as a frequency inverter capable of, for example, changing an alternating current frequency.

The system 200 comprises an inverter (power module) 210. The inverter 210 is supplied with power on the input side from a supply network 220 via a mains cable 230.

On the output side, the inverter 210 can be connected to a motor 250 via a motor cable 240.

The inverter 210 can further be located in a closed control loop by means of a controller 260 which can be configured to keep an output current of the inverter 210 constant.

This can be achieved by measuring an output current of the inverter 210 in a current measurement 270 (for example by measuring a magnetic field induced around a cable (for example motor cable 240). The result of the current measurement 270 can be a voltage proportional to the output current (for example proportional output voltage), which can be supplied to an A/D converter 280.

The A/D converter 280 can be configured to digitize the analog output voltage and thus convert it into a digital measurement signal.

Preferably, the sampling rate of the A/D converter 280 at least fulfills the Nyquist criterion. However, in some exemplary cases as described herein, the output current can also be oversampled by means of the A/D converter 280.

In some cases, a dedicated voltage measurement 290 (for example a direct output voltage) can also be provided. In such an exemplary application, the A/D converter 280 can also directly sample the output voltage concerned.

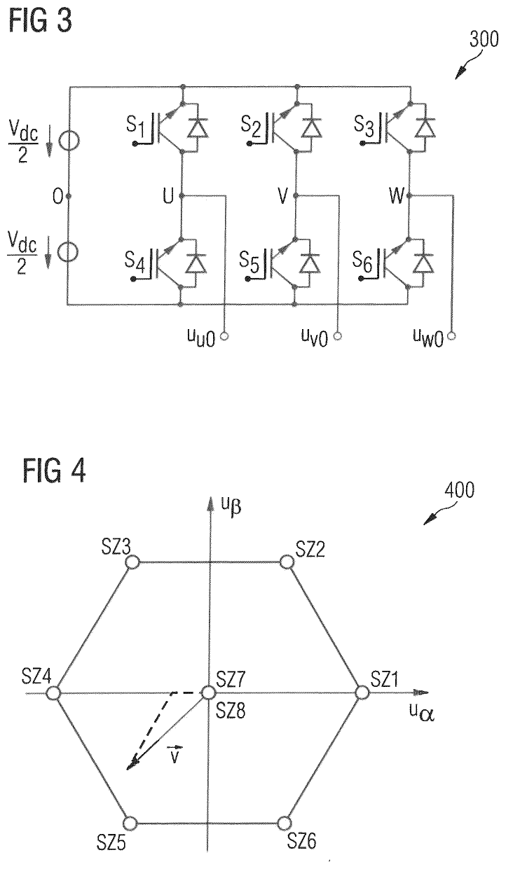

FIG. 3 shows an exemplary equivalent circuit diagram of a three-phase bridge circuit 300 according to aspects of the present invention.

The three-phase bridge circuit 300 comprises three semiconductor modules S₁-S₃ arranged in an upper half of the three-phase bridge circuit 300.

The three-phase bridge circuit 300 comprises three semiconductor modules S₄-S₆ arranged in a lower half of the three-phase bridge circuit 300.

All or at least some of the semiconductor modules S₁-S₆ can be provided as IGBTs.

In the present case, the three-phase bridge circuit 300 is operated with a direct current voltage source V_{DC}.

The three-phase bridge circuit 300 furthermore comprises three terminals uᵤ₀, uᵥ₀ and u_{w0}, via which a 3-phase load can be connected to an output of the three-phase bridge circuit 300.

Switching on the upper semiconductor modules S₁-S₃ can lead to the three terminals uᵤ₀, uᵥ₀ and u_{w0} being connected to a positive intermediate circuit potential, wherein the terminals uᵤ₀, uᵥ₀ and u_{w0} are in each case tapped at the corresponding nodes U, V, W.

The same applies to a negative intermediate circuit potential when the respective semiconductor modules S₄-S₆ arranged in the lower half of the three-phase bridge circuit 300 are switched on.

In order to avoid a short circuit, it is important not to operate the semiconductor modules S₁-S₃ arranged in the upper half of the three-phase bridge circuit 300 simultaneously with the semiconductor modules S₄-S₆ arranged in the lower half of the three-phase bridge circuit 300. On the other hand, parallel operation of semiconductor modules of one of the two halves is possible. In such a case, the current sign (+/−) of a respective phase determines whether a negative or positive intermediate circuit potential is connected to the terminals uᵤ₀, uᵥ₀ and u_{w0}.

During a mechanical and/or electronic period (fundamental period), scenarios may arise in which groups of semiconductor modules are connected for certain periods of time for longer times than can be the case for other groups of IGBTs. This can occur both in a “two level” (two control levels of the output current) and in a “multilevel” (multiple control levels of the output current) topology.

Since semiconductor modules are generally wired in groups, temporal sectors can arise so that a signal output by the power converter results from a superposition of the semiconductor modules wired in each case. Degradation of a semiconductor module can lead to a change in the period (duration, for example in the range of a half period or quarter period), which must be compensated by electronics controlling an output of the power converter and can hence, for example, be reflected in a P and/or I signal of a PI controller.

It should also be noted that each individual phase can assume two different discrete switching states (on/off). If three phases are assumed, this results in a total of 2³=8 switching states.

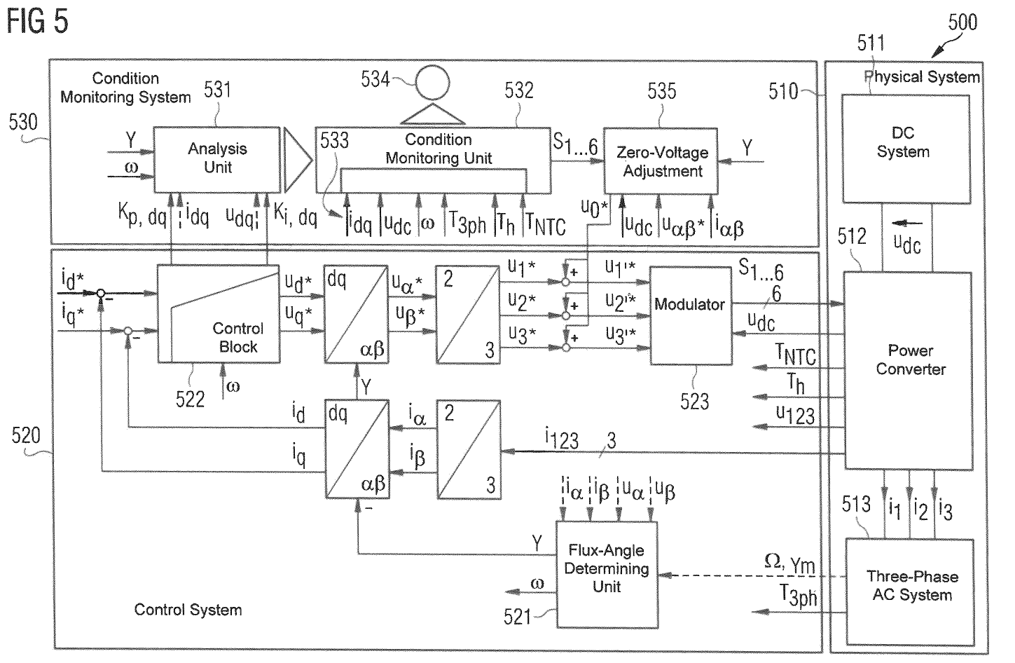

Sequential wiring of the semiconductor modules of the three-phase bridge circuit 300 leads to a total of six switching states, which can be represented in the form of a αß diagram 400 as shown in FIG. 4.

FIG. 4 shows a αß diagram 400 having a vector \vec{v} which rotates in the αß plane and is modeled with the aid of the switching states SZ1-SZ6, wherein each of the switching states SZ1-SZ6 corresponds to the wiring of a respective semiconductor module S₁-S₆.

FIG. 5 shows a signal flow diagram 500 of an interaction between a physical system 510, a control system 520 and a condition monitoring system 530 connected in parallel to the control system 520.

Herein, the physical system 510 can comprise a DC system 511. The DC system 511 can be provided for use together with a power converter for an electric drive system, which generally provides an intermediate circuit voltage via a supply (diode rectifier, AFE). However, in principle any other DC source or load can be implemented, such as, for example, a DC charging station or a photovoltaic field, etc.

The voltage U_{DC} provided by the DC system 511 can be made available to a converter (power converter) 512 or corresponding power electronics. Herein, the power converter 512 can, for example, be provided as a three-phase bridge circuit (for example the three-phase bridge circuit 300). Herein, the power converter 512 or the power electronics do not consist solely of the three-phase bridge circuit, but can also comprise sensors for current measurement, temperature monitoring, voltage measurement, etc. These sensors can also be integrated into the data-based condition monitoring.

Finally, a three-phase AC system 513 is connected to an output of the power converter 512, which can, for example, be connected to the power converter 512 by the three phases i₁, i₂ and is which were generated by the converter 512.

The three-phase AC system 513 can be provided as an electric motor or an asynchronous machine or a synchronous machine.

However, in some cases, the three-phase AC system 513 can also be a three-phase electric grid.

The control system 520 can be based on a field-oriented control (also vector control). In field-oriented control, sinusoidal alternating variables or alternating variables assumed to be largely sinusoidal (for example alternating voltages and alternating currents) are not controlled directly in their temporal instantaneous value, but in an instantaneous value adjusted for the phase angle within the period. For this purpose, the captured alternating variables are in each case transferred to a coordinate system that rotates with the frequency of the alternating variables. Within the rotating coordinate system, the alternating variables then result in DC variables to which all conventional control engineering methods can be applied.

In one possible implementation, measured current values can be transformed into a (rotor) flux-based coordinate system (dq system). Furthermore, this can be followed by decoupled control of the field-forming current (expressed by the d axis) and the torque-forming current (expressed by the q axis). A corresponding PI controller can be provided for each of the two coordinate axes (d and q). Depending on the application, a transformation angle of the flux-based coordinate system can be measured directly or estimated via modeling, as can be enabled by a flux angle determining unit 521.

In the case of asynchronous machines, the voltage/current model can be based on measured variables; in the case of synchronous machines, the rotor position can be measured directly; in the case of an electric grid, a voltage model or a phase locked loop (PLL) can be implemented based on measured variables.

A control block 522 can be used to calculate a setpoint voltage from a control deviation (for example by a setpoint/actual value comparison), which must be output by the power converter 512 in order to minimize the control deviation, ideally to zero. The setpoint voltage determined in this way can be back-transformed from the flux-based coordinate system and used as voltage setpoints for the three phases of the system under consideration.

Within the modulator 523, the switching times for the power semiconductors can be calculated from the setpoint voltages together with a measured intermediate circuit voltage and transferred to the power converter as actuation signals.

The condition monitoring 530 can be provided to evaluate the available measured and/or control variables. This can, for example, comprise a P and/or I part of the two PI controllers, measured currents and/or measured voltages. These can in each case be captured as a time profile.

In a first step, the available data can be preprocessed in a window or analysis unit 531 by means of a window that is matched to an electric or mechanical period (for example by convolution with a window function). This can be followed by the execution of a frequency analysis, for example the execution of an FFT, calculation of a Fourier series, etc. From this, the associated Fourier coefficients (amplitude and phase position) of the harmonics contained in the signal of the captured time profile can be calculated.

The execution of such a frequency analysis can be executed cyclically and thus repeatedly. This can enable monitoring of a possible change in the Fourier coefficients over time.

Based on this, a condition monitoring unit 532 can be used to determine, for example by comparing the Fourier coefficients with reference Fourier coefficients, whether degradation has progressed.

In addition, further ambient conditions 533 can be included in the data-based condition monitoring (for example humidity, ambient temperature, etc.). If the ambient conditions remain constant, a change in the Fourier coefficients can be used to draw conclusions about the advancement of degradation, which can ultimately be used to draw conclusions about an incipient fault in the system under consideration. In other words, typical fault patterns in three-phase bridge circuits can typically lead to corresponding signatures in the higher harmonics under investigation.

Based on this, the monitoring unit 532 can then determine a state of health 534 (SOH) of the system under consideration.

It should be noted that the condition monitoring 530 can be physically included in the physical system 510 (for example as part of the three-phase AC system 513). Alternatively, the condition monitoring 530 may also be installed in a remote entity (for example as a cloud service, as an edge device, etc.), which is, for example, in communicative connection with the physical system 510 and/or the control system 520.

Furthermore, a zero voltage adjustment unit 535 can (optionally) be connected to the monitoring unit 532. Based on the data provided by the monitoring unit 532, this can determine a zero voltage in such a way that it reduces a conduction time of at least one semiconductor module (for example a semiconductor module considered to be degraded) and thus the service life of the semiconductor module concerned can be further extended. The zero voltage can be added to the output signal of the control block 522 and ultimately supplied to the modulator 532 in order to determine an actuation signal which can ultimately be supplied to the power converter 512 so that the conduction time of the semiconductor module concerned (possibly also several semiconductor modules) can be adjusted.

If a phase position of the higher harmonics under consideration is determined, fault localization can be carried out to determine which of the semiconductor modules may possibly be affected by a fault or failure (and thus with an advancement of degradation), as described above.

The application of zero voltage can lead to an increase or decrease of the modulation of the power converter on all phases, in which, however, an interlinked voltage applied to load terminals remains the same. The zero voltage can preferably be selected such that the conduction time for a semiconductor module of interest is extended, as compared to semiconductor modules which are of lesser importance in the present context. Depending on the polarity of the output current of a phase, the zero voltage is then selected as positive or negative. The (second) summation voltage obtained in this way can then be supplied to a modulator and converted into a corresponding actuation signal for the at least six semiconductor modules based on a space vector modulation or carrier-based modulation method.

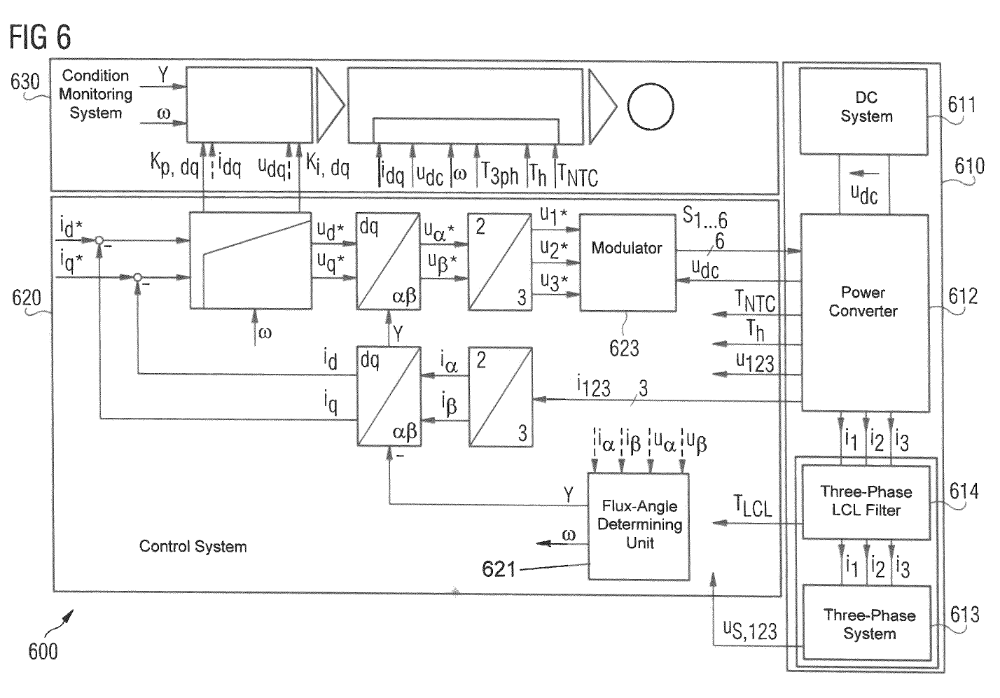

FIG. 6 shows a further signal flow diagram 600 of an interaction between a physical system 610, a control system 620 and a condition monitoring system 630 connected in parallel with the control system 620.

Herein, the physical system 610 can be provided and configured in the same way as the physical system 510 described with reference to FIG. 5, wherein (in contrast to the three-phase system 513 in FIG. 5) a three-phase LCL filter 614 has been connected upstream of the three-phase system 613. The physical system 610 may include a DC system 611 similar to the DC system 511 described above with reference to FIG. 5.

The control system 620 can be provided and configured like the control system 520 described with reference to FIG. 5.

In one possible implementation, measured current values can be transformed into a (rotor) flux-based coordinate system (dq system). Furthermore, this can be followed by decoupled control of the field-forming current (expressed by the d axis) and the torque-forming current (expressed by the q axis). A corresponding PI controller can be provided for each of the two coordinate axes (d and q). Depending on the application, a transformation angle of the flux-based coordinate system can be measured directly or estimated via modeling, as can be enabled by a flux angle determining unit 621.

The condition monitoring system 630 can be provided and configured like the condition monitoring system 530 described with reference to FIG. 5, wherein, in the present case, the control system 630 dispenses with the zero-voltage unit 535 shown in FIG. 5 (as optional).

Consequently, the control system 620 also dispenses with the supply of an adjusted zero voltage to the modulator 623 (compared to the implementation shown in FIG. 5).

The power converter 612 (which can be implemented like the power converter 512 in FIG. 5) can be used to provide condition monitoring, i.e. to determine whether a degradation state of a load following the power converter 612 has occurred. In the present case, the load can be provided as the three-phase LCL filter 614.

In a preferred implementation, in particular an integral component of a PI controller provided by the control system 620 can be used to determine whether the LCL filter 614 has degraded. In some cases, the integral component can in particular reflect a long-term change of the LCL filter 614 (or a grid).

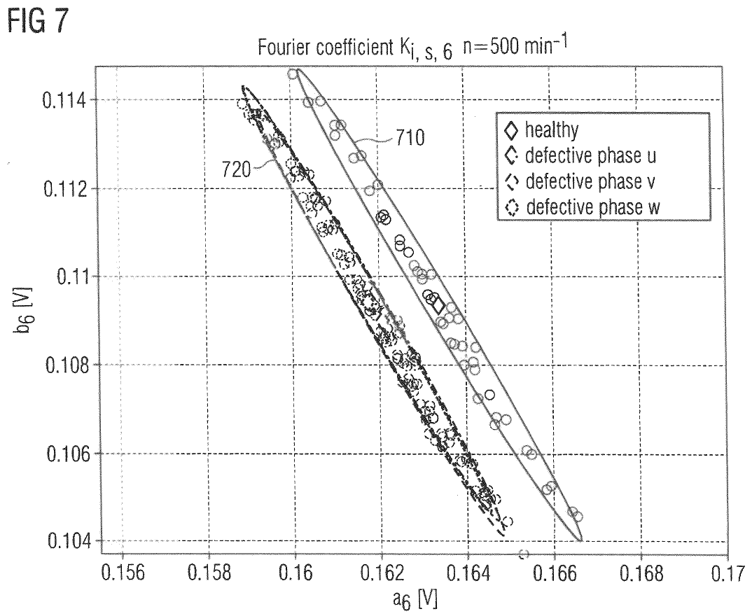

FIG. 7 shows exemplary event clouds resulting from a plotting of Fourier coefficients b₆ against as for a plurality of (first) time profiles. The underlying captured time profiles refer to a rotational speed of the electric drive unit of 500 revolutions per minute.

The Fourier coefficients aₖ or bₖ where k∈N can be derived from the application of a Fourier transform (for example a fast Fourier transform (FFT)) to a (first) captured time profile of an output voltage and/or an output current of the power converter. The Fourier coefficients aₖ or bₖ can be normalized in such a way that they contribute to the reconstruction of the captured time profile f(t) according to Equation 1. The time profile f(t) can therefore be described by a Fourier series representation as follows:

$$f ( t ) ∼ \frac{{a}_{0}}{2} + {{\sum }_{k = 1}}^{∞} ( {a}_{k} cos ( \frac{2 π}{T} kt ) + {b}_{k} sin ( \frac{2 π}{T} kt ) ) \qquad Equation 1$$

In Equation 1, a₀ describes a static contribution to the signal (for example a DC component), T a period duration of a frequency component k under consideration for the signal f(t).

Herein, the event cloud 710 describes a state at which the power converter is to be regarded as healthy, i.e. at which no (significant) degradation of the power converter has yet occurred. The event cloud 710 extends over a range of −0.162 V to 0.166 V for a₆ and over a range of 0.104 V to 0.114 V for b₆.

Furthermore, FIG. 7 shows a plurality of overlapping event clouds (indicated by event cloud 720) for a defective state of the load (i.e. a state which can be associated with an advancement of the degradation state of the load). In the present case, the event cloud 720 extends in a range of approximately 0.159 V to approximately 0.165 V for a₆ and in a range of 0.104 V to 0.114 V for b₆.

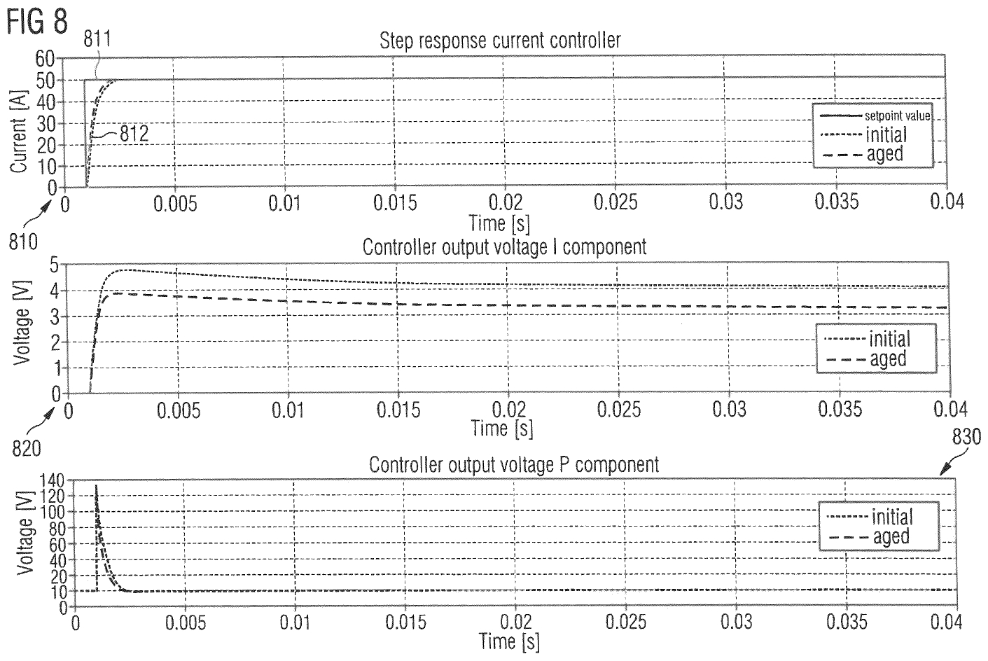

FIG. 8 shows an exemplary application for determining a degradation state of a load connected downstream of a power converter (and/or of an intermediate circuit).

Diagram 810 shows an exemplary profile of a current in A, which can be measured as the output current of a current controller, plotted against time for an expected setpoint profile 811. Furthermore, diagram 810 shows an initial current profile 812 (i.e. immediately after implementation of the power grid or a grid filter, which is to be subjected to condition monitoring as a load). Furthermore, diagram 810 also shows the exemplary profile of the current as it can occur in the case of an aged power grid (dashed line).

As can be seen in diagram 810, the expected setpoint profile corresponds to a step function, i.e. a sudden increase in current from 0 A to 50 A. This setpoint profile is reflected in a real system by the initial current profile 812 which reflects the setpoint profile in a rounded form (for a time interval of less than 4 ms). For a time >5 ms, the current profile assumes a constant value of approximately 50 A.

In the event of a degradation progression, the initial current profile 812 can be reproduced as an example, but shifted by an offset (for example by less than 1 A) toward larger currents.

In this way, by determining that a shift in the current flow has occurred, it can be concluded from the initial current profile 812 that an underlying degradation is progressing.

Diagram 820 shows an exemplary profile of a controller output voltage in V (the integral component of a PI controller), such as can, for example, be supplied to a power converter in order to control an output current (or an output voltage) of the power converter to a desired setpoint value, plotted against a time profile.

The voltage profile of the controller output voltage shown in diagram 820 can be used to control the current profile (as shown in diagram 810) to a constant value of, for example, 50 A.

Diagram 820 shows the profile of the voltage profile for an initial state (in which, for example, a power grid and/or a grid filter is in a non-degraded state; solid lines) and for a degraded state (dashed line).

While the current profile shown as an example for the initial state initially rises from 0 V to approximately 5 V (for a time interval of <4 ms), by way of example, this approximately follows an exponential decay behavior and changes to a constant voltage value of approximately 4 V for a time of >25 ms.

In the present case, in the event of degradation, the profile of the initial state is reproduced, but with a voltage shifted by approximately 0.9 V toward lower voltage values.

On the other hand, diagram 830 shows an exemplary profile of a controller output voltage in V (of the proportional component of a PI controller), as can, for example, be supplied to a power converter in order to control an output current (or an output voltage) of the power converter to a desired setpoint value, plotted against a time profile.

The voltage profile of the controller output voltage shown in diagram 830 can be used to control the current profile (as shown in diagram 810) to a constant value of, for example, 50 A.

Diagram 830 shows the profile of the voltage profile for an initial state (in which for example a power grid and/or a grid filter is in a non-degraded state; solid lines) and for a degraded state (dashed line).

In the present case, the voltage profile increases abruptly from 0 V to 130 V then follows an exponential decay behavior and assumes a constant value of almost 0 V for times >4 ms.

In the present case, the presence of degradation can manifest itself in a shift of the controller output voltage during the decay behavior toward a lower voltage (for example by approximately 1 V), wherein otherwise the qualitative profile of the output voltage curve, which reflects the initial state, is reproduced and thus remains qualitatively unchanged.

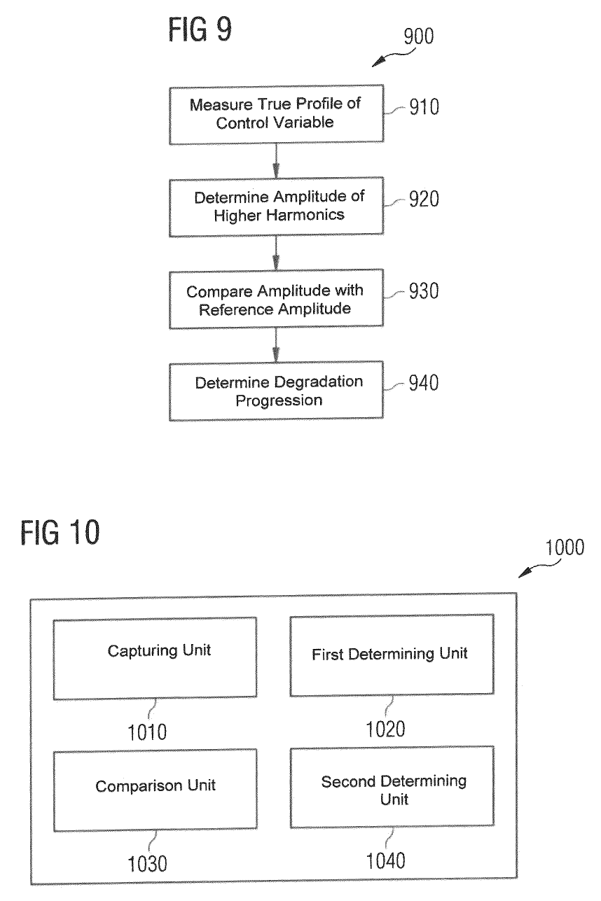

FIG. 9 shows a flowchart of an exemplary computer-implemented method 900 for determining a degradation progression of a load following a power converter and/or intermediate circuit according to one aspect of the present invention.

In step 910, a time profile of a control variable is captured which is intended to control an output voltage and/or an output current of the power converter and/or the intermediate circuit and wherein the output voltage and/or the output current is intended to be supplied to the load.

In step 920, an amplitude of at least one higher harmonic of a fundamental oscillation of the captured time profile is determined.

In step 930, the amplitude is compared with a reference amplitude, wherein the reference amplitude is associated with a known degradation progression of the load.

In step 940, the degradation progression of the load is determined based on the comparison.

FIG. 10 shows an exemplary computer-implemented apparatus 1000 for determining a degradation progression of a power converter according to one aspect of the present invention. The computer-implemented apparatus 1000 comprises a capturing unit 1010, a first determining unit 1020, a comparison unit 1030 and a second determining unit 1040.

The capturing unit 1010 is configured to capture a time profile of a control variable which is intended to control an output voltage and/or an output current of the power converter and/or the intermediate circuit and wherein the output voltage and/or the output current is intended to be supplied to the load.

The first determining unit 1020 is configured to determine an amplitude of at least one higher harmonic of a fundamental oscillation of the captured time profile.

The comparison unit 1030 is configured to compare the amplitude with a reference amplitude, wherein the reference amplitude is associated with a known degradation progression of the load.

The second determining unit 1040 is configured to determine the degradation progression of the load based on the comparison.

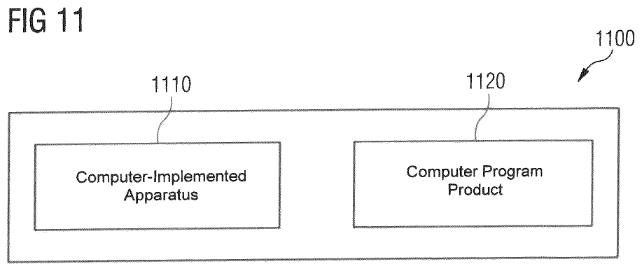

FIG. 11 shows an exemplary system 1100 for determining a degradation progression of a power converter according to one aspect of the present invention. The system 1100 includes a computer-implemented apparatus 1110 and a computer program product 1120.

The computer-implemented apparatus 1110 can be configured as described herein.

The computer program product 1120 can be configured as described herein.

While the invention has been illustrated and described in connection with currently preferred embodiments shown and described in detail, it is not intended to be limited to the details shown since various modifications and structural changes may be made without departing in any way from the spirit and scope of the present invention. The embodiments were chosen and described in order to explain the principles of the invention and practical application to thereby enable a person skilled in the art to best utilize the invention and various embodiments with various modifications as are suited to the particular use contemplated.

Independent of the grammatical term usage, individuals with male, female or other gender identities are included within the term.

What is claimed as new and desired to be protected by Letters Patent is set forth in the appended claims and includes equivalents of the elements recited therein:

What is claimed is:

1. A computer-implemented method for determining a degradation progression of a load connected downstream of a power converter or of an intermediate circuit, comprising:
measuring a time profile of a control variable controlling an output voltage or an output current of the power converter or of the intermediate circuit, the output voltage or the output current intended to be supplied to the load;
determining an amplitude of at least one higher harmonic of a fundamental oscillation of the captured time profile;
comparing the amplitude with a reference amplitude that is associated with a known degradation progression of the load; and
determining the degradation progression of the load based on the comparison.

2. The computer-implemented method of claim 1, wherein the load is selected from an electric drive unit, a combination of a resistor and an inductor, a cable, a filter and a power grid.

3. The computer-implemented method of claim 1, wherein the control variable is a proportional (P) component, an integral (I) component of a PI controller or a value provided by a fault memory.

4. The computer-implemented method of claim 1, wherein determining the amplitude further comprises determining an amplitude of a DC component, a 1^{st} harmonic, a 2^{nd} harmonic or a 6^{th} harmonic.

5. The computer-implemented method of claim 1, further comprising:
measuring a parameter associated with the load, wherein the parameter is a temperature of the load, a speed of an electric drive unit, a rotor position angle of an electric drive unit or an ambient temperature of the load; and
determining the degradation progression of the load based on the comparison and the measured parameter.

6. The computer-implemented method of claim 1, wherein at least one of the power converter and the intermediate circuit is part of a grid-side power-converter system.

7. The computer-implemented method of claim 1, further comprising:
measuring a plurality of time profiles;
determining a respective amplitude of the at least one harmonic for each of the measured time profiles;
determining a variance of the determined amplitudes; and
determining the degradation progression based at least in part on the determined variance.

8. The computer-implemented method of claim 7, further comprising:
determining a phase associated with the higher harmonic;
comparing the phase with a reference phase; and
determining the degradation progression of the load based on the comparison of the amplitude and the comparison of the phase.

9. The computer-implemented method of claim 1, wherein, when the load is a power grid, the control of the power converter is configured to at least one of provide reactive power, compensate asymmetric loads and perform frequency stabilization.

10. The computer-implemented method of claim 1, wherein the power converter or the intermediate circuit is part of a photovoltaic system or of a wind turbine.

11. The computer-implemented method of claim 1, wherein the power converter is constructed as a 3-phase 2-level inverter comprising
at least one semiconductor module implemented as an insulated gate bipolar transistor, IGBT, or as a SiC metal oxide semiconductor field-effect transistor, MOSFET.

12. The computer-implemented method of claim 11, wherein the power converter comprises six semiconductor modules.

13. A computer program product embodied on a non-transitory computer-readable medium and comprising instructions which, when the instructions are read into a memory of a computer and executed by a processor of the computer, cause the computer to execute the method as claimed in claim 1.

14. A computer-implemented apparatus for determining a degradation progression of a load connected downstream of a power converter or an intermediate circuit of the power converter, comprising:
a capturing unit for capturing a time profile of a control variable controlling an output voltage or an output current of the power converter or of the intermediate circuit supplied to the load;
a first determining unit for determining an amplitude of at least one higher harmonic of a fundamental oscillation of the captured time profile;
a comparison unit for comparing the amplitude with a reference amplitude hat is associated with a known degradation progression of the load; and
a second determining unit for determining the degradation progression of the load based on the comparison.

15. The computer-implemented apparatus of claim 14, further comprising an execution unit designed to execute the computer program product of claim 13.

16. The computer-implemented apparatus of claim 14, further comprising a further execution unit designed to execute the method of claim 1.

17. A system for determining a degradation progression of a power converter, comprising:
a computer-implemented apparatus for determining a degradation progression of a load connected downstream of a power converter or an intermediate circuit of the power converter, comprising:
a capturing unit for capturing a time profile of a control variable controlling an output voltage or an output current of the power converter or of the intermediate circuit supplied to the load;
a first determining unit for determining an amplitude of at least one higher harmonic of a fundamental oscillation of the captured time profile;
a comparison unit for comparing the amplitude with a reference amplitude hat is associated with a known degradation progression of the load;
a second determining unit for determining the degradation progression of the load based on the comparison; and
the computer program product of claim 13.
